(19) United States
(12) Patent Application Publication
(10) Pub. No.: US 2009/0257155 A1
(43) Pub. Date: Oct. 15, 2009

(54) PERSISTENT SWITCH SYSTEM

(76) Inventor: Robert James McGregor, Oxfordshire (GB)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/361,803

(22) Filed: Jan. 29, 2009

(30) Foreign Application Priority Data
Feb. 5, 2008 (GB) 0802034.9

(51) Int. Cl. H01L 39/16

(52) U.S. Cl. 361/19

(57) ABSTRACT

A persistent switches for use in a superconducting system includes a resistive element, a persistent switch connected in parallel with the resistive element and an inductive element connected to the persistent switch and the resistive element such that the inductive element limits a current in a hotspot of the persistent switch.

### BACKGROUND OF THE INVENTION

1. Field of the Invention

The present invention relates to persistent switches used in superconducting systems.

2. Description of the Prior Art

A persistent switch is a length of electrical conductor containing superconducting material whose resistance can be changed from a zero or very low-resistance (closed position) to a high resistance (open position) by the action of a heater, magnetic field, or other means to prevent superconductivity. These switches are commonly used to route currents in superconducting circuits.

Superconductivity is a phenomenon occurring in certain materials at extremely low temperatures, characterized by exactly zero electrical resistance and the exclusion of the interior magnetic field. The electrical resistance of a metallic conductor decreases gradually as the temperature is lowered. However, in ordinary conductors such as copper and silver, impurities and other defects impose a lower limit of resistance. Resistance will not drop below this lower limit. Even near absolute zero a real sample of copper shows a non-zero resistance. The resistance of a superconductor, on the other hand, drops abruptly to zero when the material is cooled below its “critical temperature”.

Superconductivity occurs in a wide variety of materials, including simple elements like tin and aluminum, various metallic alloys and some heavily-doped semiconductors. A superconducting material is in a superconducting state when operated within certain ranges of temperature, external magnetic field, and current. Persistent switches operate by changing either the temperature, current or magnetic field of the superconducting material from within the superconductivity range to an operating point outside of the superconducting range, thus switching its operation from superconducting to a resistive state.

Conventional persistent switches of the thermal type operate by heating the superconducting material to a temperature above its superconducting critical temperature. A phenomenon called quench is an event (usually unwanted) in which some superconducting part of a circuit or component becomes resistive (as a result of its operating conditions or because of a disturbance), following which the heating effect of current flowing through the resistive zone releases substantial further heat which causes the resistive zone to grow rapidly.

Under certain circumstances a persistent switch is operated from its open towards its closed condition but is unable to close fully because of heat generated in the switch element itself by the action of an externally imposed voltage source. A typical voltage source might be a resistive element connected in parallel with a large current flowing in it. A stable resistive zone called hotspot can exist inside a switch with an applied voltage. A small current flows through the switch which depends on the resistance of the hotspot. Cooling of the hotspot reduces its resistance and tends to increase current in the switch, which increases the heat dissipation and prevents further cooling. Switch closure occurs only if heat is lost from the hotspot faster than it can be generated.

Closure does occur spontaneously in some circumstances, but the conditions for closure depend on the applied voltage, its source resistance, and on the characteristics of the switch. Often, closure occurs only if the external current is made smaller than the application requires or if the resistance is made smaller than is realistically achievable. In general it might be necessary to reduce the external voltage or current to close the switch. Closing the switch under full working conditions might be a problem.

### SUMMARY OF THE INVENTION

An object of the present invention is to provide a persistent switch system that facilitates switch closure.

The above object is achieved in accordance with the invention by a persistent switch system for use in a superconducting circuit, having a resistive element, a persistent switch, connected in parallel to the resistive element, and at least one inductive element connected to the persistent switch and the resistive element, wherein the inductive element is adapted to limit a current in a hotspot of the persistent switch.

The basis of the present invention is to add an inductive element to the switch such that a hotspot within a switch will collapse to zero faster than the external circuit can deliver energy to the hotspot. The inductive element prevents current in a hotspot of the persistent switch to rise too fast and by this limits the current in the hot spot since it prevents the formation of the hotspot.

In a preferred embodiment of the present invention the at least one inductive element is connected in series with the persistent switch. The advantage is that the inductive element can be made in the form of an internal inductance within the switch in the circuit. The interaction between the inductive element and the time-dependent characteristics of the switch hotspot leads to switch closure.

In a further preferred embodiment of the present invention the at least one inductive element is connected in series with the resistive element. The advantage is that the inductive element can be made integral to the resistive element.

In a further preferred embodiment of the present invention the inductive element is made from superconducting wire. The advantage is that the inductive element can be located in the same cryogenic environment as the switch and can be cooled to a low-resistance state, thereby reducing the losses.

In a further preferred embodiment of the present invention the inductive element is made from non-superconducting wire. This allows the inductive element to be located outside the cryogenic environment, in situations where this may be more desirable. The inductive element can be made in the form of an internal inductance within the resistive element. This has practical and manufacturing advantages depending on the circumstances.

In a further preferred embodiment of the present invention the inductive element is fitted with voltage limiting devices. Voltage limiting devices such as certain diodes protect the switch from stresses associated with energy stored in the inductive element. If switch quenching occurs or the switch is opened by external action, its current flow must be diverted quickly to avoid potential burn-out or voltage overstress. The inductive element current cannot change quickly and so the diodes provide an alternative path for the current.

In a further preferred embodiment of the present invention a switch recloser comprising the persistent switch system is formed by an arrangement of an inductive element fitted with diodes and a resistive link. In the event of switch quench current is diverted into the resistive link and the diode conducts for a short period while current transfers into the inductive element. The switch cools back to a superconducting state and recloses, assisted by the inductive element. After a short period the current in the switch returns to its original value, except for any change in current which may have been caused by the transient voltages across the switch.

In a further preferred embodiment of the present invention, the switch recloser can also be used in a superconducting magnet system.

### DESCRIPTION OF THE DRAWINGS

FIG. 1 is a schematic overview of a conventionally used persistent switch.

FIG. 2 is a schematic overview of one embodiment of the proposed persistent switch system.

FIG. 3 is a schematic overview of an alternative embodiment of the proposed persistent switch system.

FIG. 4 is a schematic overview showing an inductance fitted with diodes.

FIG. 5 is a schematic overview of the proposed switch recloser according to an embodiment of the present invention.

FIG. 6 is a schematic overview of a superconducting magnet system, comprising a switch recloser according to an embodiment of the present invention.

### DESCRIPTION OF THE PREFERRED EMBODIMENTS

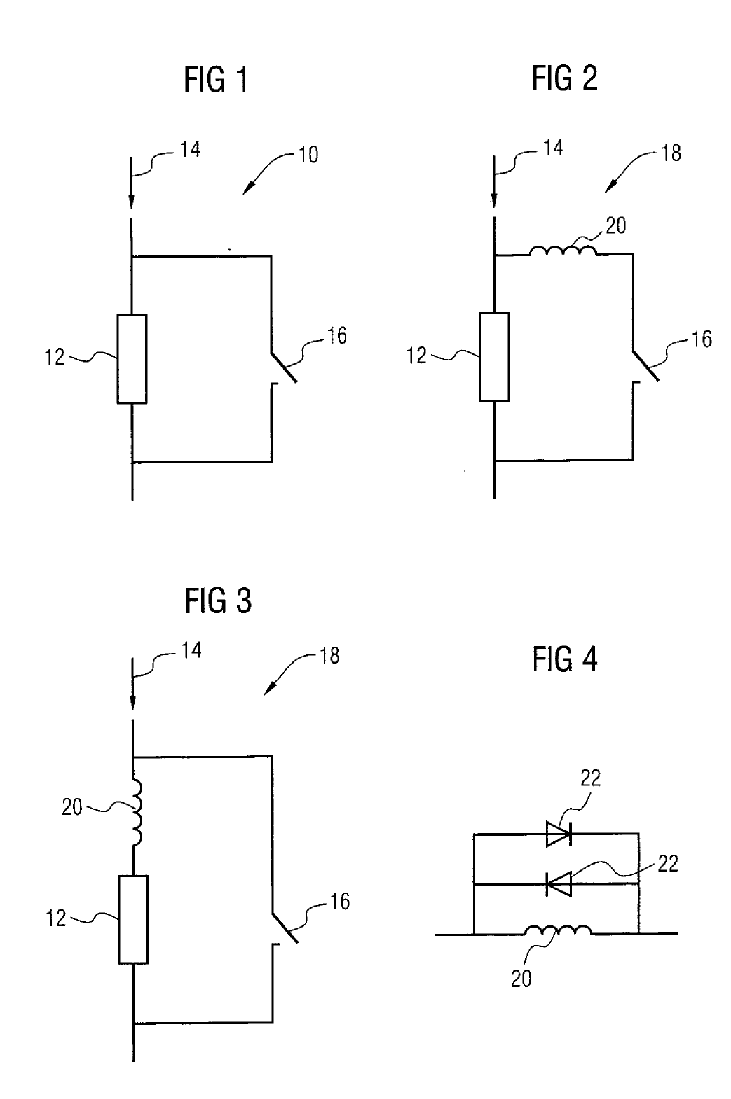

Referring to FIG. 1, an overview of a conventionally used persistent switch system 10 is shown. The resistive element 12 is attached to a wire with current flowing through it whose direction is indicated by the arrow 14. A persistent switch 16 which is generally a wire of superconducting material is connected in parallel to the resistive element 12. The resistance of the persistent switch 16 can be changed from a zero or very low-resistance value to a high resistance value by the action of a heater, magnetic field or other means to influence superconductivity. When the resistance is very low the switch is referred to as closed and when it is very high the switch is referred to as open. Persistent switches are commonly used to route currents in superconducting circuits.

A persistent switch 16 is operated from its open to its closed condition by varying the resistance. Under certain circumstances it has been observed that the switch is unable to close fully because of heat generated in the switch element itself by the action of an externally imposed voltage source like the resistive element 12 with a large current flowing through it. A stable resistive zone (hotspot) might exist inside the switch and therefore a small current flows through the switch which depends on the resistance of the hotspot. Cooling of the hotspot reduces its resistance and tends to increase the current in the switch, which increases the dissipation and prevents further cooling. Switch closure occurs only if heat is lost from the hotspot faster than it can be generated.

Referring to FIG. 2, an overview of the proposed persistent switch system 18 according to an embodiment of the present invention is shown. An inductive element 20 is added in series with the persistent switch 16. With an inductive element 20 of appropriate inductance a hotspot within a switch will collapse to zero faster than the external circuit can deliver energy to the hotspot.

The inductive element 20 is adapted to limit the current in the hotspot of the persistent switch. The inductive element actually resists change in the current through the hotspot and by delaying the current change in the circuit it gives the hotspot sufficient time to cool such that heat is lost from the hotspot faster than it can be generated. This idea exploits an interaction between the inductive element and the time-dependent characteristics of any switch hotspot. The switch can be made to close by making the inductance of the inductive element greater than a minimum value which depends on the switch characteristics (like current, resistance etc). The hotspot has some properties similar to those of an active electronic device which, in conjunction with the inductance, can create a circuit without a stable operating state, resulting in switch closure.

A switch made from superconducting wire is typically of wound construction, usually wound bifilar or non-inductively. Usual switch winding practice minimizes inductance. The required inductance might be obtained internally by appropriate winding of the switch although this depends on the circumstances.

FIG. 3 shows an overview of an alternate embodiment of the persistent switch system 18 according to the present invention. The inductive element 20 is connected in series with the resistive element 12. The inductive element 20 can be made from non-superconducting wire. This allows a resistive inductive element to be located outside the cryogenic environment, in situations where this may be more desirable.

Also the inductive element 20 can be realized in the form of an internal inductance within the resistive element 12. This has practical and manufacturing advantages depending on the circumstances.

Referring to FIG. 4, a schematic overview of an inductive element 20 fitted with diodes 22 is shown. The inductive element 20 is fitted with voltage limiting devices such as diodes 22 to protect the switch from stresses associated with energy stored in the inductive element 20. If the switch quenches or is accidentally opened by external action, its current flow must be diverted quickly to avoid potential burn-out or voltage overstress. The inductive element current cannot change quickly and so the diodes 22 provide an alternative path for the current. Two diodes 22 are shown because in some applications it will be desirable that current can flow around the inductive element 20 in both directions.

In typical applications involving switch closure, circuit voltages in the steady state are of the order of mV and so the diodes 22 have no significant bias and do not affect the function of the inductive element 20.

FIG. 5 shows a schematic overview of the switch recloser 24 according to an embodiment of the present invention. The inductive element 20, diodes 22 and a resistive element 12 is arranged as shown to form a device acting as a switch recloser 24. In the event of switch quench, current is diverted into the resistive element 12 and a diode 22 conducts for a short period while current transfers into the inductive element 20. The switch cools back to a superconducting state and recloses, assisted by the inductive element 20. After a short period the current in the switch returns to its original value, except for any change in current which may have been caused by the transient voltages across the switch.

It is to be noted that the switch recloser 24 can also be formed with the circuit shown in FIG. 2 but the recloser is best implemented using the FIG. 3 circuit. During normal operation with the switch closed in FIG. 3, no current flows in the inductive element. Hence, unlike FIG. 2, it cannot create a stray field which might affect operation of the system.

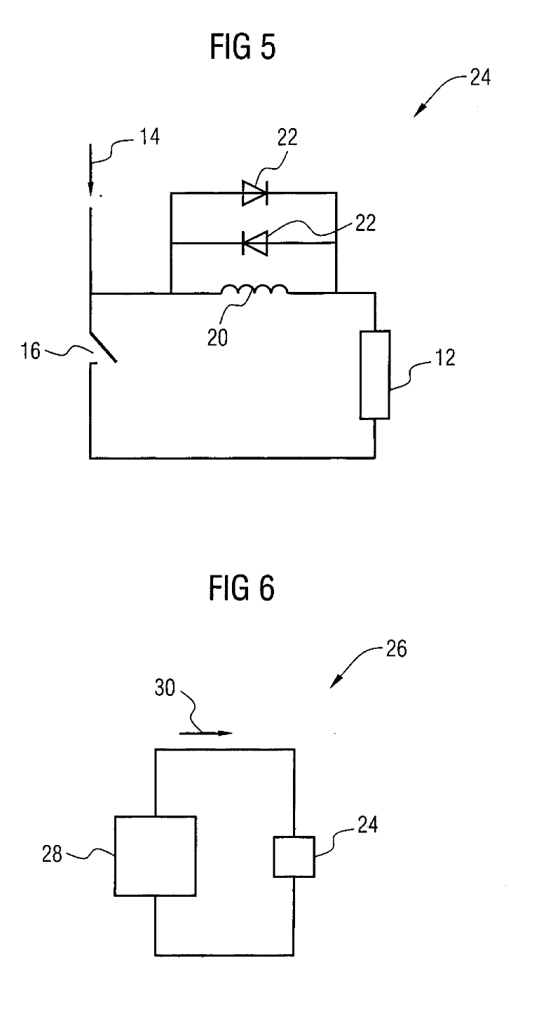

FIG. 6 shows the superconducting magnet system 26 embodying the switch recloser 24 according to the present invention. It has a superconducting magnet 28 with the magnetic current flowing as indicated by the arrow 30 and the switch recloser 24.

In the event of spontaneous quench, the system will return to low-loss (persistent) mode after the interruption. This prevents the magnet run down over an extended time with significant dissipation in the non-superconducting path comprising external shorting link and internal current leads. Such dissipation causes undesirable helium boil-off which would increase the cost of a service visit to restore normal operation. It may also cause damage to the system depending on the thermal design of the leads, an issue which might arise during the design of a magnet. There will be some loss of field during the interruption but the system is designed so that the loss of field during one or more switch quench events is within tolerable limits for extended operation of the system.

A magnetic resonance system (MRI) system is normally designed to operate correctly over a range of magnet current, so that the system can function for extended periods in the presence of some losses.

Summarizing, the present invention relates to persistent switches used in superconducting systems. The proposed persistent switch system 18 comprises a resistive element 12, a persistent switch 16 connected in parallel to the resistive element 12 and an inductive element 20 connected to the persistent switch 16 and the resistive element 12 such that the inductive element 20 is adapted to limit a current in a hotspot of the persistent switch 16.

Although the invention has been described with reference to specific embodiments, this description is not meant to be construed in a limiting sense. Various modifications of the disclosed embodiments, as well as alternate embodiments of the invention, will become apparent to persons skilled in the art upon reference to the description of the invention. It is therefore contemplated that such modifications can be made without departing from the spirit or scope of the present invention as defined.

I claim as my invention:

1. A switch recloser for use in a superconducting circuit, comprising:
a resistive element;
a persistent switch, connected in parallel with the resistive element; and
at least one inductive element connected to the persistent switch and the resistive element, the inductive element limiting a current in a hotspot of the persistent switch, wherein the inductive element being fitted with voltage limiting devices.

2. The switch recloser according to claim 1, wherein the at least one inductive element is connected in series with the persistent switch.

3. The switch recloser according to claim 1, wherein the at least one inductive element is connected in series with the resistive element.

4. The switch recloser according to claim 1, wherein the inductive element is made from superconducting wire.

5. The switch recloser according to claim 1, wherein the inductive element is made from non-superconducting wire.

6. A superconducting magnet system comprising:
a superconducting circuit;
a switch recloser connected in said superconducting circuit, said switch recloser comprising a resistive element, a persistent switch, connected in parallel with the resistive element. and at least one inductive element connected to the persistent switch and the resistive element, the inductive element limiting a current in a hotspot of the persistent switch, wherein the inductive element being fitted with voltage limiting devices.
